(19) United States
(12) Patent Application Publication
(10) Pub. No.: US 2018/0062582 A1
(43) Pub. Date: Mar. 1, 2018

(54) LOW-NOISE AMPLIFIER HAVING INTER-STAGE FILTER

(71) Applicant: SKYWORKS SOLUTIONS, INC., Woburn, MA (US)

(72) Inventor: Ibrahim Engin PEHLIVANOGLU, Costa Mesa, CA (US)

(21) Appl. No.: 15/687,903

(22) Filed: Aug. 28, 2017

Related U.S. Application Data
(60) Provisional application No. 62/380,852, filed on Aug. 29, 2016.

(51) Int. Cl. H03F 1/22; H03F 3/213; H03F 3/195; H04B 1/16

(52) U.S. Cl. CPC H03F 1/223; H03F 3/213; H03F 3/195; H04B 1/16; H03F 2200/451; H03F 2200/294; H03F 2200/411; H03F 2200/75; H03F 2200/72; H03F 2200/165

(57) ABSTRACT

Low-noise amplifier having inter-stage filter. In some embodiments, an amplifier assembly for amplifying a signal can include an input amplification stage and an output amplification stage. The amplifier assembly can further include an inter-stage filter implemented between the input amplification stage and the output amplification stage.

### CROSS-REFERENCE TO RELATED APPLICATION(S)

This application claims priority to U.S. Provisional Application No. 62/380,852 filed Aug. 29, 2016, entitled LOW-NOISE AMPLIFIER HAVING INTER-STAGE FILTER, the disclosure of which is hereby expressly incorporated by reference herein in its respective entirety.

### BACKGROUND

### Field

The present disclosure relates to radio-frequency amplifiers such as low-noise amplifiers.

### Description of the Related Art

In radio-frequency (RF) applications, an amplifier is utilized to amplify a signal. For transmission, a signal is typically amplified by a power amplifier so that the amplified signal is transmitted through an antenna with a desired power. For reception, a relatively weak signal received through an antenna is typically amplified by a low-noise amplifier. The amplified signal with little or no noise added is then processed further by a receiver circuit.

### SUMMARY

According to a number of implementations, the present disclosure relates to an amplifier assembly for amplifying a signal. The amplifier assembly includes an input amplification stage, an output amplification stage, and an inter-stage filter implemented between the input amplification stage and the output amplification stage.

In some embodiments, the amplifier can be a low-noise amplifier. The low-noise amplifier can be implemented in a cascode configuration. The input amplification stage can include a common emitter transistor, and the output amplification stage can include a common base transistor. The input amplification stage can include a common source transistor, and the output amplification stage can include a common gate transistor.

In some embodiments, each of the input amplification stage and the output amplification stage can be configured to provide amplification for a signal in a first frequency band. The inter-stage filter can be a band-pass filter configured for the first frequency band. The inter-stage filter can be a notch filter configured to block a second frequency band outside of the first frequency band.

In some embodiments, the input amplification stage and the output amplification stage can be parts of a first amplification path, such that the input amplification stage is a first input stage, the output amplification stage is a first output stage, and the inter-stage filter is a first inter-stage notch filter. In some embodiments, the amplifier assembly can further include a second amplification path having a second input stage and a second inter-stage notch filter. In some embodiments, the second amplification path can further include the first output stage of the first amplification path as a common output stage. The second inter-stage notch filter can be configured to block the first frequency band.

In some embodiments, each of the first inter-stage notch filter and the second inter-stage notch filter can include a parallel combination of a capacitance and an inductance. Each of the first inter-stage notch filter and the second inter-stage notch filter can further include a grounding path at a node between the parallel combination and the corresponding input stage, with the grounding path including a series combination of a capacitance and an inductance. The second inter-stage notch filter can further include an additional grounding path at the node, the additional grounding path including a capacitance.

In some embodiments, the first frequency band can have an upper limit of a frequency range that is lower than a lower limit of a frequency range of the second frequency band. The first frequency band can include, for example, a B2 band, and the second frequency band can include, for example, a B4 band.

In some embodiments, each of the input amplification stage, the output amplification stage, and the inter-stage filter can be configured to process a radio-frequency signal. In some embodiments, the inter-stage filter can be implemented at a node between the input amplification stage and the output amplification stage, with at least the node of the amplifier assembly being configured to operate in a current mode. The inter-stage filter can be configured without a constraint associated with impedance matching in a filter that is external to the amplifier assembly.

In some teachings, the present disclosure relates to a method for amplifying a signal. The method includes amplifying an input signal by an input amplification stage to generate a partially amplified signal, filtering the partially amplified signal to generate a filtered signal, and amplifying the filtered signal by an output amplification stage to generate an amplified signal as an output.

In some implementations, the present disclosure relates to an amplifier die that includes a semiconductor substrate and an amplifier including an input amplification stage and an output stage, with the amplifier being implemented on the semiconductor substrate. The amplifier die further includes an inter-stage filter implemented between the input amplification stage and the output amplification stage, with the inter-stage filter being formed on the semiconductor substrate.

In some embodiments, the amplifier can be a low-noise amplifier. The low-noise amplifier can be implemented in, for example, a cascode configuration. The semiconductor substrate can include, for example, a silicon substrate. The semiconductor substrate can include, for example, a silicon-on-insulator substrate.

In some implementations, the present disclosure relates to a packaged module for processing a signal. The packaged module includes a packaging substrate configured to receive a plurality of components, and an amplifier implemented on the packaging substrate. The amplifier includes an input amplification stage and an output stage, and an inter-stage filter implemented between the input amplification stage and the output amplification stage, with the inter-stage filter being formed on the packaging substrate.

In some embodiments, the amplifier and the inter-stage filter can be implemented on a common semiconductor die. The amplifier can be a low-noise amplifier configured to amplify a received signal from an antenna. The packaged module can be a diversity receive module, and the antenna can be a diversity antenna.

According to some implementations, the present disclosure relates to a wireless device that includes an antenna configured to receive a signal, and an amplifier assembly in communication with the antenna and configured to amplify the signal. The amplifier assembly includes an input amplification stage and an output stage, and an inter-stage filter implemented between the input amplification stage and the output amplification stage. The wireless device further includes a transceiver in communication with the amplifier assembly and configured to process the amplified signal.

In some embodiments, the wireless device can be a cellular phone configured to operate in one or more cellular bands.

In accordance with some teachings, the present disclosure relates to a carrier-aggregation architecture that includes a first amplification path having an input stage, an output stage, and an inter-stage filter implemented between the input stage and the output stage. The first amplification path is configured to provide a first signal in a first frequency band. The carrier-aggregation architecture further includes a second amplification path having an input stage, an output stage, and an inter-stage filter implemented between the input stage and the output stage. The second amplification path is configured to provide a second signal in a second frequency band. The carrier-aggregation architecture further includes an output path common to an output of the first amplification path and an output of the second amplification path to allow aggregation of the first signal and the second signal in the output path.

In some embodiments, each of the first amplification path and the second amplification path can be configured to amplify a signal received by an antenna, such that the aggregated signal in the output path is a downlink aggregated signal. The output stage of the first amplification path and the output stage of the second amplification path can be implemented as a common output stage. The output stage of the first amplification path and the output stage of the second amplification path can be implemented as a common output stage. Each of the input stage of the first amplification path and the common output stage, and the input stage of the second amplification path and the common output stage, can be implemented in a cascode configuration.

In some embodiments, each of the inter-stage filter of the first amplification path and the inter-stage filter of the second amplification path can be a notch filter. The notch filter of the first amplification path can be configured to block the second frequency band, and the notch filter of the second amplification path can be configured to block the first frequency band.

In some embodiments, the carrier-aggregation architecture can further include a band-pass filter implemented upstream of each of the first amplification path and the second amplification path. The carrier-aggregation architecture can further include a phase shifter implemented between the band-pass filter and the corresponding amplification path.

In accordance with some implementations, the present disclosure relates to a receiver die that includes a semiconductor substrate, and a first amplification path implemented on the semiconductor substrate and including an input stage, an output stage, and an inter-stage filter implemented between the input stage and the output stage, with the first amplification path being configured to provide a first signal in a first frequency band. The receiver die further includes a second amplification path implemented on the semiconductor substrate and including an input stage, an output stage, and an inter-stage filter implemented between the input stage and the output stage, with the second amplification path being configured to provide a second signal in a second frequency band. The receiver die further includes an output node common to an output of the first amplification path and an output of the second amplification path to allow aggregation of the first signal and the second signal through the output node.

According to some implementations, the present disclosure relates to a receiver module that includes a packaging substrate configured to receive a plurality of components, and a first amplification path implemented on the packaging substrate and including an input stage, an output stage, and an inter-stage filter implemented between the input stage and the output stage, with the first amplification path being configured to provide a first signal in a first frequency band. The receiver module further includes a second amplification path implemented on the packaging substrate and including an input stage, an output stage, and an inter-stage filter implemented between the input stage and the output stage, with the second amplification path being configured to provide a second signal in a second frequency band. The receiver module further includes an output path implemented on the packaging substrate. The output path is common to an output of the first amplification path and an output of the second amplification path to allow aggregation of the first signal and the second signal through the output path.

In some embodiments, the first amplification path and the second amplification path can be implemented on a common semiconductor die. The receiver module can be a diversity receive module.

According to some teachings, the present disclosure relates to a wireless device that includes an antenna configured to receive a signal, and a carrier-aggregation system configured to receive the signal from the antenna. The carrier-aggregation system includes a first amplification path having an input stage, an output stage, and an inter-stage filter implemented between the input stage and the output stage, with the first amplification path being configured to provide a first signal in a first frequency band. The carrier-aggregation system further includes a second amplification path having an input stage, an output stage, and an inter-stage filter implemented between the input stage and the output stage, the second amplification path being configured to provide a second signal in a second frequency band. The carrier-aggregation system further includes an output path common to an output of the first amplification path and an output of the second amplification path to allow aggregation of the first signal and the second signal in the output path. The wireless device further includes a transceiver in communication with the carrier aggregation system and configured to process the aggregated signal.

In some embodiments, the wireless device can be a cellular phone configured to operate in a plurality of cellular bands. The antenna can be a diversity antenna.

In some embodiments, at least the first amplification path and the second amplification path can be implemented on a common semiconductor die. In some embodiments, the carrier aggregation system can part of a diversity receive module.

According to some teachings, the present disclosure relates to a cascode amplifier that includes an input stage and an output stage implemented in a cascode configuration. The cascode amplifier can further include an inter-stage circuit implemented between the input stage and the output stage, and configured to operate in a current mode to condition a signal provided by the input stage.

In some embodiments, the cascode amplifier can be implemented as a low-noise amplifier. In some embodiments, the inter-stage circuit can include an inter-stage filter circuit.

In some teachings, the present disclosure relates to a carrier-aggregation architecture that includes a first amplification path having an input stage, an output stage, and an inter-stage circuit implemented between the input stage and the output stage, with the first amplification path being configured to provide a first signal in a first frequency band. The carrier-aggregation architecture further includes a second amplification path having an input stage, an output stage, and an inter-stage circuit implemented between the input stage and the output stage, with the second amplification path being configured to provide a second signal in a second frequency band. The carrier-aggregation architecture further includes an output path common to an output of the first amplification path and an output of the second amplification path to allow aggregation of the first signal and the second signal in the output path.

In some embodiments, the output stage of the first amplification path and the output stage of the second amplification path can be implemented as a common output stage. In some embodiments, the inter-stage circuit of each of the first and second amplification paths can include an inter-stage filter circuit.

In some teachings, the present disclosure relates to a radio-frequency integrated circuit die that includes a semiconductor substrate and a cascode amplifier implemented on the semiconductor substrate. The cascode amplifier includes an input stage and an output stage implemented in a cascode configuration, and an inter-stage circuit implemented between the input stage and the output stage, and configured to operate in a current mode to condition a signal provided by the input stage.

In some teachings, the present disclosure relates to a radio-frequency module that includes a packaging substrate configured to receive a plurality of components, and a cascode amplifier implemented on the packaging substrate. The cascode amplifier includes an input stage and an output stage implemented in a cascode configuration, and an inter-stage circuit implemented between the input stage and the output stage, and configured to operate in a current mode to condition a signal provided by the input stage.

In some embodiments, the cascode amplifier can be implemented on one of the plurality of components in a form of a semiconductor die.

In some teachings, the present disclosure relates to a wireless device that includes an antenna and a receiver circuit having a cascode amplifier that includes an input stage and an output stage implemented in a cascode configuration. The cascode amplifier further includes an inter-stage circuit implemented between the input stage and the output stage, and configured to operate in a current mode to condition a signal provided by the input stage.

### BRIEF DESCRIPTION OF THE DRAWINGS

FIG. 1 depicts a radio-frequency (RF) amplifier having a plurality of amplification stages, and an inter-stage filter implemented among such amplification stages.

FIG. 2 shows an example configuration of a typical receive (Rx) path for a signal received by an antenna.

FIG. 3 shows an example of how a low-noise amplifier (LNA) of FIG. 2 can be implemented.

FIG. 4 shows an example configuration of an Rx path for a signal received by an antenna.

FIG. 5 shows an example of how an LNA of FIG. 4 can be implemented.

FIG. 6 shows a typical carrier-aggregation configuration in which a plurality of RF signals can be aggregated into a single signal path.

FIG. 7 shows an LNA assembly capable of providing carrier-aggregation functionality.

FIG. 8 shows an LNA assembly capable of providing carrier-aggregation functionality to the example of FIG. 7.

FIG. 9 shows an LNA assembly that can be a more specific example of the LNA assembly of FIG. 8.

FIG. 10 shows plots of noise measured at an output of the LNA assembly of FIG. 9 when only the first amplification path is active.

FIG. 11 shows comparisons of noise figure performance plots as a function of frequency for the example configuration of FIG. 9.

FIG. 12 shows comparisons of gain (S21) performance plots as a function of frequency for the example configuration of FIG. 9.

FIG. 13 shows comparisons of input return loss (S11) plots as a function of frequency for the example configuration of FIG. 9.

FIG. 14 shows comparisons of output return loss (S22) plots as a function of frequency for the example configuration of FIG. 9.

FIG. 15 shows an LNA having a band-pass filter implemented between an input stage transistor and cascode stage transistor of a cascode configuration.

FIG. 16 shows that in some embodiments, some or all of an LNA having one or more features as described herein can be implemented on a semiconductor die.

FIG. 17 shows that in some embodiments, a packaged module having one or more features as described herein can include a semiconductor die that is similar to the example of FIG. 16.

FIG. 18 shows that in some embodiments, a packaged module having one or more features as described herein can include a first semiconductor die having an LNA implemented thereon, some of one or more inter-stage filters implemented on the first die, and the rest of the one or more inter-stage filters implemented on another die, outside of a die, or any combination thereof.

FIG. 19 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

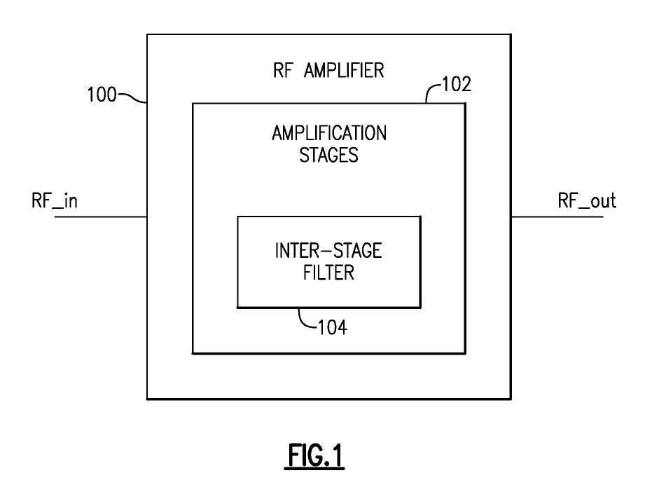

FIG. 1 depicts a radio-frequency (RF) amplifier 100 having a plurality of amplification stages 102, and an inter-stage filter 104 implemented among such amplification stages. As described herein, such an RF amplifier can be configured to receive one or more input signals (RF_in), process such signal(s), and output one or more amplified signals (RF_out). As also described herein, in some embodiments, such an RF amplifier can be configured to provide carrier-aggregation (CA) functionality, such that a plurality of input signals can be processed and combined into a common signal path.

Various examples are described herein in the context of RF amplifiers; however, it will be understood that one or more features of the present disclosure can also be implemented in other types of amplifiers. Various examples are also described herein in the context of such RF amplifiers being low-noise amplifiers (LNAs) such as cascode LNAs; however, it will be understood that one or more features of the present disclosure can also be implemented in other types of RF amplifiers.

In some embodiments, an inter-stage filter having one or more features as described herein can be implemented as an on-chip filter (e.g., on the same die as a corresponding LNA). Such an inter-stage filter can provide, for example, filtering capability with noise figure performance suitable for carrier-aggregation operation in switchless LNAs. Additional details concerning such switchless LNAs are disclosed in U.S. Publication No. 2015/0296515, entitled CIRCUITS AND METHODS RELATED TO SWITCHLESS CARRIER AGGREGATION IN RADIO-FREQUENCY RECEIVERS, the disclosure of which is hereby incorporated by reference herein in its entirety and to be considered part of the specification of the present application.

It is noted that in some embodiments, an inter-stage filter having one or more features as described herein can be utilized to filter out-of-band (relative to a given frequency band) signals or frequency components. In some applications, such out-of-band filtering does not need to provide very high attenuation such as in a surface-acoustic-wave (SAW) filter. For example, in some embodiments, an inductor/capacitor (LC) based filter can be implemented on-chip (e.g., on the same die as the corresponding LNA), and be configured to remove or reduce added noises in a carrier-aggregation mode of operation. Examples related to such removal or reduction of noises are described herein in greater detail.

It is further noted that in some embodiments, since a signal being amplified by an LNA is typically in a current mode when within the LNA (e.g., in a mid-node in the LNA), an inter-stage filter implemented within the LNA does not need to be constrained with impedance matching (e.g., 50-ohm matching) requirement. Accordingly, such an inter-stage filter can be easier to implement than a counterpart filter requiring impedance matching functionality.

It is further noted that in some embodiments, an inter-stage filter having one or more features as described herein can be easier to design and implement, since such an inter-stage filter is substantially self-contained within the corresponding LNA. Accordingly, such an inter-stage filter can be smaller and more cost-effective to implement than an off-chip filter.

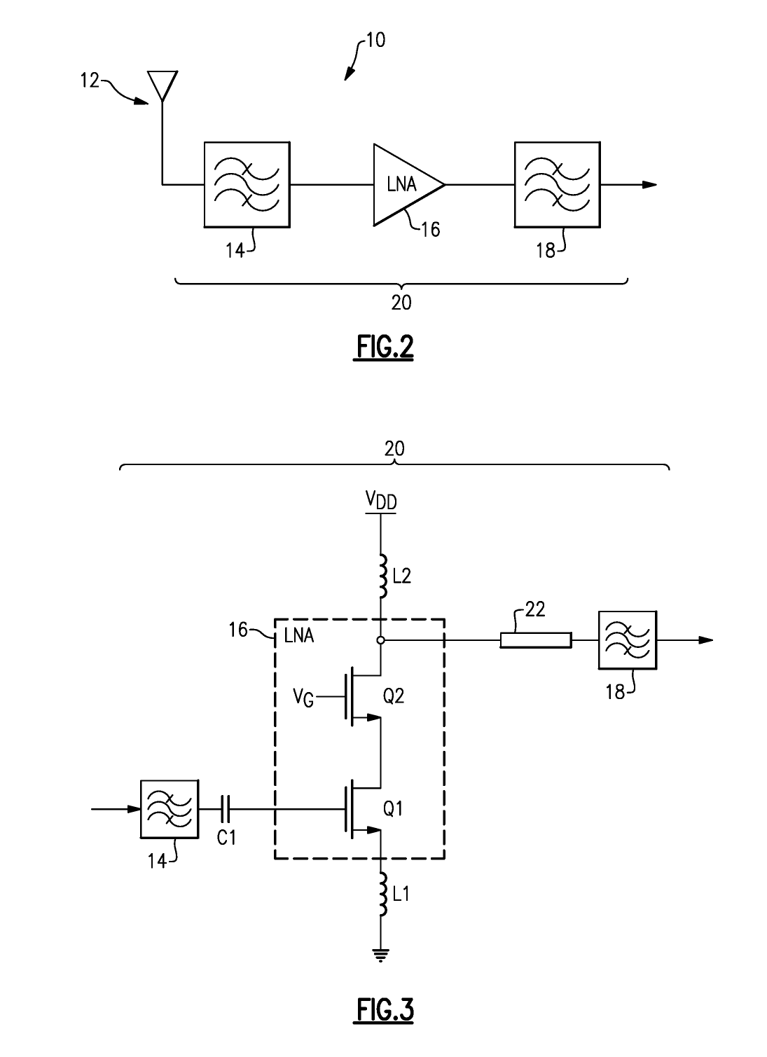

FIG. 2 shows an example configuration 10 of a receive (Rx) path 20 for a signal received by an antenna 12. For a given frequency band, such a signal is typically filtered by a band-pass filter 14 associated with the frequency band, and then provided to an LNA 16. An amplified signal from the LNA 16 can be further filtered by another band-pass filter 14 also associated with the frequency band to further define the amplified signal.

FIG. 3 shows an example of how the LNA 16 of FIG. 2 can be implemented. In FIG. 3, an LNA 16 can be implemented in a cascode configuration where an input RF signal passed through the first band-pass filter 14 and a DC-block capacitance C1 is provided to a gate of a first field-effect transistor (FET) Q1. A source of Q1 is shown to be coupled to ground (e.g., through an inductance L1), and a drain of Q1 is shown to be coupled to a source of a second FET Q2. A gate of Q2 can be provided with a gate voltage Vg, and a drain of Q2 can be an output of the LNA 16. Such an output of the LNA 16 can be coupled to the second band-pass filter 18 through, for example, a transmission line 22. The drain of Q2 can be provided with a supply voltage Vdd through, for example, a choke inductance L2.

In the example of FIG. 3, the signal received by the LNA 16 is routed through the gate and drain of Q1, and source and drain of Q2. Thus, Q1 is operated as a common source device, and Q2 is operated as a common gate device. It is noted that Q1 is sometimes referred to as an input stage or an RF stage; and Q2 is sometimes referred to as a cascode stage.

In the example of FIG. 3, the cascode configuration of the LNA 16 is described in the context of FETs. It will be understood that an LNA having one or more features as described herein can also be implemented with, for example, bipolar-junction transistors (BJTs). For example, Q1 can be a first BJT operated as a common emitter device, such that an input signal is received at a base of Q1 and output at a collector of Q1, with an emitter of Q1 being coupled to ground. Q2 can be a second BJT operated as a common base device, such that the output of Q1 is provided to an emitter of Q2 and output through a collector of Q2 as an output of the LNA. A base of Q2 can be provided with a bias voltage for such cascode operation.

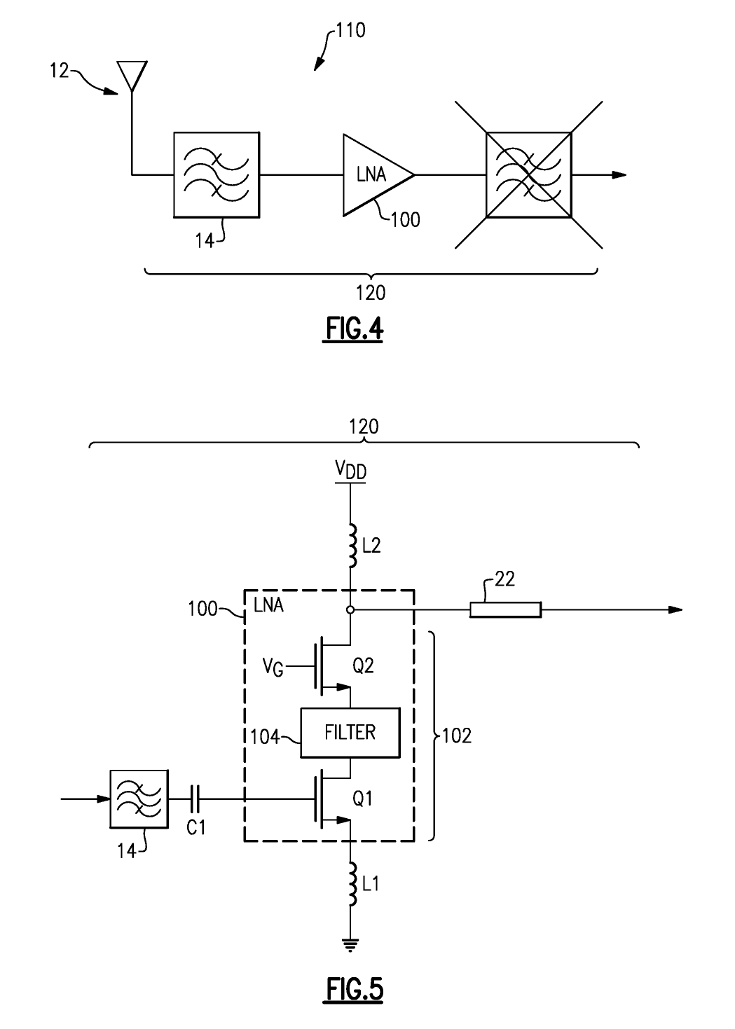

FIG. 4 shows an example configuration 110 of a receive (Rx) path 120 for a signal received by an antenna 12. For a given frequency band, such a signal can be filtered by a band-pass filter 14 associated with the frequency band, similar to the example of FIG. 2. Such a filtered signal can be provided to an LNA 100 having or more features as described herein. An amplified signal from the LNA 100 can be routed for further processing downstream. In contrast to the example of FIG. 2, however, the example configuration 110 of FIG. 4 shows an absence of a post-LNA filter (18 in FIG. 2) in the receive path 120. As described herein, some or all of filtering functionality associated with such a post-LNA filter can be addressed by an inter-stage filter.

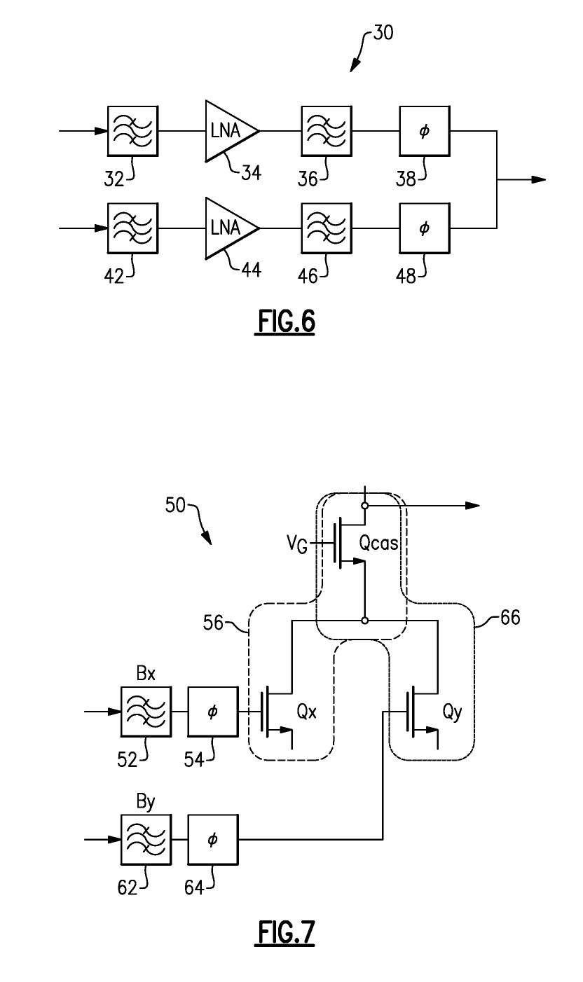

FIG. 5 shows an example of how the LNA 100 of FIG. 4 can be implemented. In FIG. 5, an LNA 100 can be implemented in a cascode configuration where an input RF signal passed through the first (e.g., band-pass) filter 14 and a DC-block capacitance C1 is provided to a gate of a first FET Q1, similar to the example of FIG. 3. A source of Q1 is shown to be coupled to ground (e.g., through an inductance L1), and a drain of Q1 is shown to be coupled to a source of a second FET Q2 through an inter-stage filter 104. A gate of Q2 can be provided with a gate voltage Vg, and a drain of Q2 can be an output of the LNA 100. Such an output of the LNA 100 can be routed through, for example, a transmission line 22 for further processing downstream. The drain of Q2 can be provided with a supply voltage Vdd through, for example, a choke inductance L2.

In the example of FIG. 5, the signal received by the LNA 100 is routed through the gate and drain of Q1, and source and drain of Q2, similar to the example of FIG. 3. Thus, Q1 is operated as a common source device, and Q2 is operated as a common gate device. It is noted that Q1 is sometimes referred to as an input stage or an RF stage; and Q2 is sometimes referred to as a cascode stage.

In the example of FIG. 5, the cascode configuration of the LNA 100 is described in the context of FETs, similar to the example of FIG. 3. It will be understood that an LNA having one or more features as described herein can also be implemented with, for example, bipolar-junction transistors (BJTs). For example, Q1 can be a first BJT operated as a common emitter device, such that an input signal is received at a base of Q1 and output at a collector of Q1, with an emitter of Q1 being coupled to ground. Q2 can be a second BJT operated as a common base device, such that the output of Q1 is provided to an emitter of Q2 (through an inter-stage filter 104) and output through a collector of Q2 as an output of the LNA. A base of Q2 can be provided with a bias voltage for such cascode operation.

In the example of FIGS. 4 and 5, the inter-stage filter (104 in FIG. 5) can be configured such that the output of the LNA 100 has a better frequency band definition than, for example, the input of the LNA 100. Thus, in some embodiments, the inter-stage filter 104 can be implemented as a band-pass filter configured to further filter the band-pass filtered (e.g., by the pre-LNA filter 14) and partially amplified signal from Q1. In some embodiments, the inter-stage filter 104 can also be implemented to filter one or more frequency bands outside of the frequency band associated with the pre-LNA filter 14. Such an inter-stage filter can be, for example, a notch-filter configured to filter a specific frequency band while substantially passing other frequencies.

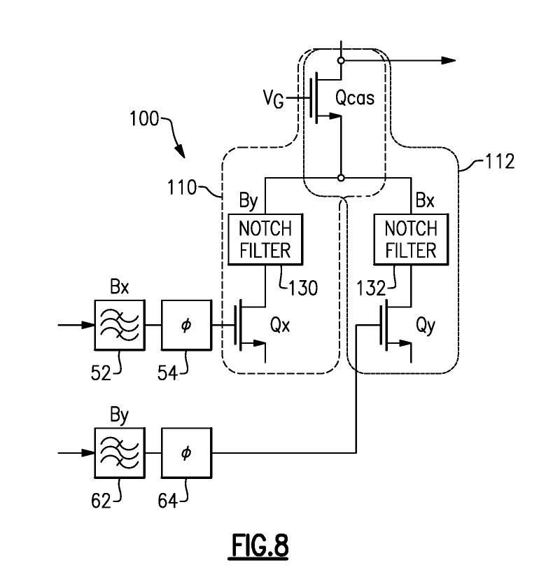

In some embodiments, the foregoing notch-filtering of the output of Q1 can be utilized in a carrier-aggregation application. Examples related to such carrier-aggregation application are described herein in reference to FIGS. 6-14.

FIG. 6 shows a carrier-aggregation configuration 30 in which a plurality of RF signals (e.g., two RF signals associated with first and second frequency bands Bx, By) can be aggregated into a single signal path. A first frequency band (Bx) signal can be processed by a first amplification path having a band-pass filter 32, an LNA 34, and a second band-pass filter 36. Similarly, a second frequency band (By) signal can be processed by a second amplification path having a band-pass filter 42, an LNA 44, and a second band-pass filter 46. Such amplified and filtered signals can be combined or aggregated into a common signal path as shown. To facilitate such aggregation, the amplified and filtered signals can be provided with appropriate phase shifts by their respective phase shifters 38, 48. It is noted that in the example of FIG. 6, the LNAs 34, 44 do not have inter-stage filters.

In the example carrier-aggregation configuration of FIG. 6, a switching circuit can be provided upstream of the first filters 32, 42 so as to allow each of the first and second amplification paths to be operated by itself in a non-carrier-aggregation mode, or to allow both of the first and second amplification paths to be operated simultaneously in a carrier-aggregation mode. Accordingly, such a configuration can be considered to be a switched carrier-aggregation configuration.

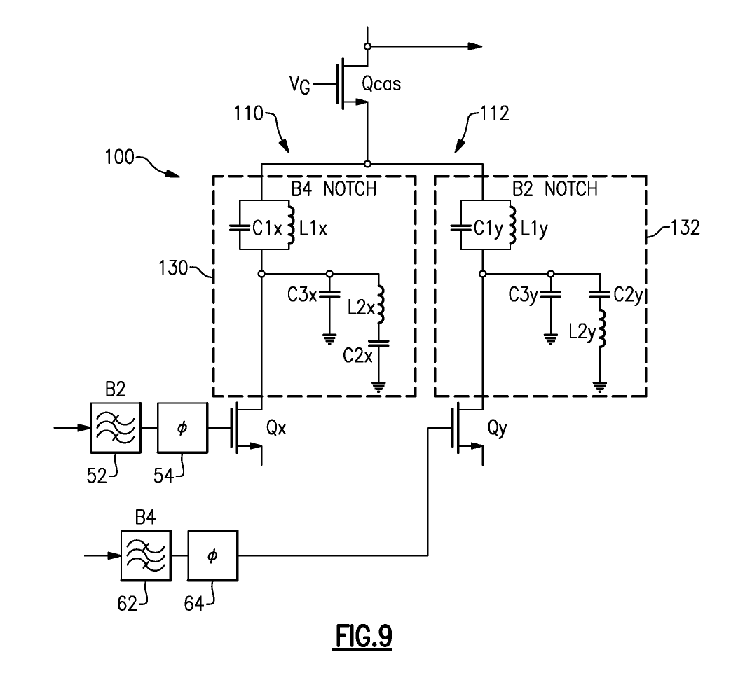

FIG. 7 shows an LNA assembly 50 capable of providing carrier-aggregation functionality that is similar to the examples of switchless carrier-aggregation disclosed in the above-mentioned U.S Publication No. 2015/0296515. In the LNA assembly 50, a first frequency band (Bx) signal can be processed by a first amplification path having a band-pass filter 52, a phase shifter 54, and an LNA indicated as 56. Similarly, a second frequency band (By) signal can be processed by a second amplification path having a band-pass filter 62, a phase shifter 64, and an LNA indicated as 66.

The first LNA 56 is shown to include a common-source transistor Qx and a common-gate transistor Qcas arranged in a cascode configuration. The second LNA 66 is shown to include a common-source transistor Qy and the common-gate transistor Qcas arranged in a cascode configuration, such that the common-gate transistor Qcas is a common cascode device for both of Qx and Qy. A drain of Qcas is shown to be a common output for the first and second LNAs 56, 66. It is noted that in the example of FIG. 7, the LNAs 56, 66 do not have inter-stage filters.

FIG. 8 shows an LNA assembly 100 capable of providing carrier-aggregation functionality similar to the example of FIG. 7. However, in the LNA assembly 100, each of the two example LNAs 110, 112 is shown to include an inter-stage notch filter (130 or 132). More particularly, a first frequency band (Bx) signal can be processed by a first amplification path having a band-pass filter 52, a phase shifter 54, and an LNA indicated as 110. Similarly, a second frequency band (By) signal can be processed by a second amplification path having a band-pass filter 62, a phase shifter 64, and an LNA indicated as 112.

The first LNA 110 is shown to include a common-source transistor Qx and a common-gate transistor Qcas arranged in a cascode configuration, with an inter-stage notch filter 130 implemented between a drain of Qx and a source of Qcas. The second LNA 112 is shown to include a common-source transistor Qy and the common-gate transistor Qcas arranged in a cascode configuration, with an inter-stage notch filter 132 implemented between a drain of Qy and the source of Qcas. Accordingly, the common-gate transistor Qcas is a common cascode device for both of Qx and Qy. A drain of Qcas is shown to be a common output for the first and second LNAs 110, 112.

In the example of FIG. 8, the first amplification path includes the band-pass filter 52 configured to pass the first frequency band Bx, and the inter-stage notch filter 130 configured to block the second frequency band By. Similarly, the second amplification path includes the band-pass filter 62 configured to pass the second frequency band By, and the inter-stage notch filter 132 configured to block the first frequency band Bx.

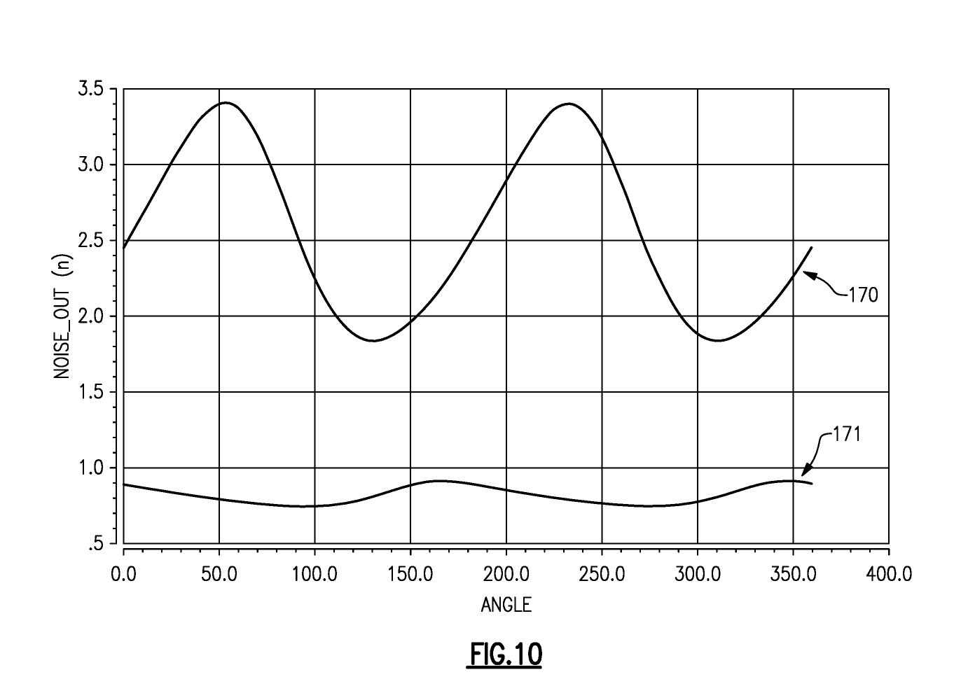

FIG. 9 shows an LNA assembly 100 that can be a more specific example of the LNA assembly 100 of FIG. 8. More particularly, examples of inter-stage notch filters 130, 132 are shown for cellular frequency bands B2 and B4 as the first and second frequency bands (Bx and By in FIG. 8). It is noted that the example cellular frequency band B2 has a transmit (Tx) frequency range of 1.850 GHz to 1.910 GHz and a receive (Rx) frequency range of 1.930 GHz to 1.990 GHz. The example frequency range B4 has a Tx frequency range of 1.710 GHz to 1.755 GHz and an Rx frequency range of 2.110 GHz to 2.155 GHz. It is further noted that downlink carrier-aggregation of the B2 and B4 bands can pose challenges.

In the example of FIG. 9, the inter-stage notch filter 130 can include a parallel combination of a capacitance C1x and an inductance L1x implemented between the drain of Qx and the source of Qcas. The inter-stage notch filter 130 can further include a ground coupling path having a series arrangement of an inductance L2x and a capacitance C2x, from the drain of Qx. A capacitance C3x to ground from the drain of Qx represents a parasitic capacitance associated with Qx, and such a capacitance may or may not be included in the inter-stage notch filter 130. For the foregoing example B4 band, notch filtering functionality can be provided by example values of capacitances and inductances listed in Table 1.

TABLE 1

| Circuit element | Example value | |
|---|---|---|
| C1x | 1.65 | pF |
| L1x | 4.0 | nH |
| L2x | 11 | nH |
| C2x | 1.0 | pF |
| C3x | 0.3 | pF |

In the example of FIG. 9, the inter-stage notch filter 132 can include a parallel combination of a capacitance C1y and an inductance L1y implemented between the drain of Qy and the source of Qcas. The inter-stage notch filter 132 can further include a ground coupling path having a series arrangement of a capacitance C2y and an inductance L2y, from the drain of Qy. A capacitance C3y to ground from the drain of Qy represents a parasitic capacitance associated with Qy, and such a capacitance may or may not be included in the inter-stage notch filter 132. For the foregoing example B2 band, notch filtering functionality can be provided by example values of capacitances and inductances listed in Table 2.

TABLE 2

| Circuit element | Example value | |
|---|---|---|
| C1y | 1.8 | pF |
| L1y | 3.0 | nH |
| C2y | 15 | nH |
| L2y | 1.0 | pF |
| C3y | 0.3 | pF |

It will be understood that the cellular bands B2 and B4 described in reference to FIG. 9 are examples of two bands that can be carrier-aggregated. Other groups of cellular bands, including those disclosed herein, can also be carrier-aggregated, assuming that within a given group the corresponding bands do not overlap.

It will also be understood that the notch filters 130 and 132 described in reference to FIG. 9 are examples of notch filters that can be utilized. It will be understood that other notch filter configurations can also be utilized. Further, values of various circuit elements for any of the foregoing notch filters can be selected to provide desired filtering functionalities for any of the foregoing frequency bands.

As described herein, and referring to the more general example of FIG. 8, it is desirable to have the first frequency band (Bx) signal be well defined when the signal emerges from the inter-stage notch filter 130 that blocks the second frequency band By. Similarly, it is desirable to have the second frequency band (By) signal be well defined when the signal emerges from the inter-stage notch filter 132 that blocks the first frequency band Bx. Such well-defined nature of the signal at the corresponding inter-stage node is desirable whether the LNA assembly 100 is being operated in a carrier-aggregation mode or a single-band mode (Bx or By).

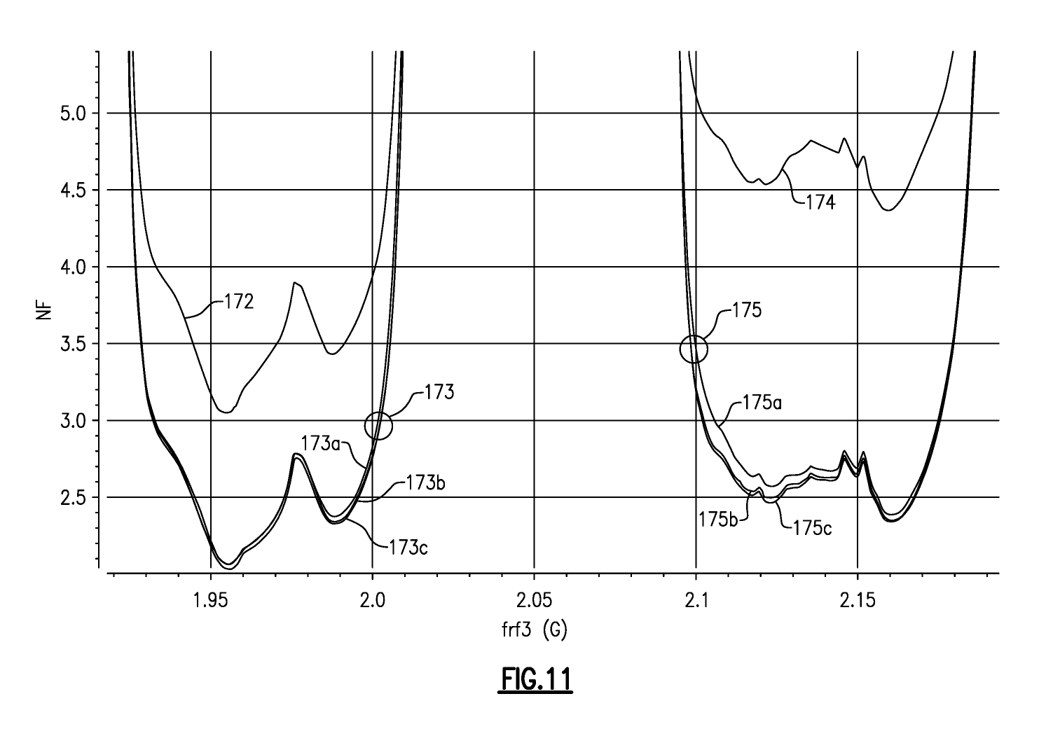

Such well-defined nature of a given signal can be affected by a number of factors, such as noise and S parameters associated with corresponding filter(s). FIGS. 10-14 show examples of filtering performance that can be provided by inter-stage notch filters as described herein, in the context of the example configuration of FIG. 9 and the example values of capacitances and inductances of Tables 1 and 2. In such examples, Q value of each inter-stage notch filter is assumed to be 20. For the B2 notch filter 132, the inductance L2y is assumed to have a Q value of 20.

FIG. 10 shows plots of noise measured at an output of the LNA assembly (e.g., after an output matching circuit (not shown in FIG. 9)) when only the first amplification path is active (for B2). The upper plot (170) is an output noise (V/sqrt(frequency in Hz)) as a function of transmission line angle between the B2 filter (52 in FIG. 9) and Qx, when the inter-stage notch filter (130 in FIG. 9) is absent (e.g., similar to the configuration of FIG. 7 where Bx=B2 and By=B4). The lower plot (171) is an output noise (V/sqrt(frequency in Hz)) as a function of the same transmission line angle range, when the inter-stage notch filter 130 is present as shown in FIG. 9. One can readily see that in the latter plot (171), the noise associated with the B4 band is suppressed significantly by the inter-stage notch filter 130, as desired.

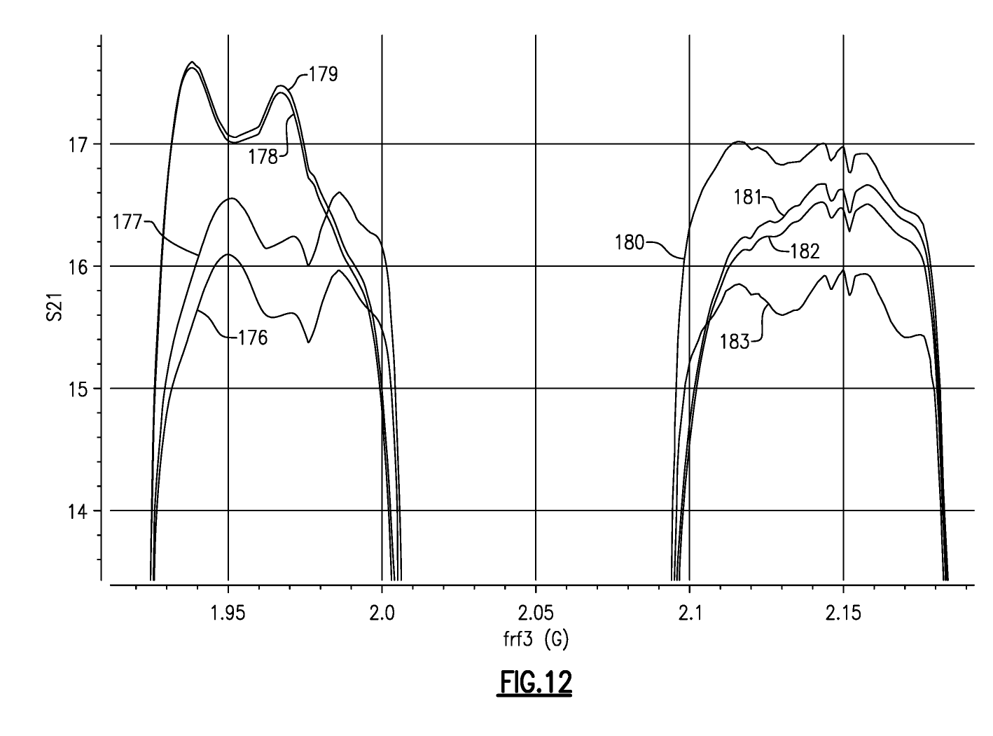

FIG. 11 shows comparisons of noise figure (in dB) performance plots as a function of frequency for the example configuration of FIG. 9 and Tables 1 and 2. The group of plots on the left side of FIG. 11 correspond to B2 (1.930 GHz to 1.990 GHz for Rx), and the group of plots on the right side correspond to B4 (2.110 GHz to 2.155 GHz for Rx). The plots indicated as 172 and 174 are noise figures in B2 and B4 in a B2/B4 carrier-aggregation mode, respectively, when inter-stage notch filters (130, 132 in FIG. 9) are absent (e.g., similar to the configuration of FIG. 7). The tightly clustered group of three plots collectively indicated as 173 are for noise figure in B2 in the B2/B4 carrier-aggregation mode when inter-stage notch filters are present as shown in FIG. 9 (upper-most plot 173a), noise figure in B2 in a B2-only non-carrier-aggregation mode when inter-stage notch filters are absent (middle plot 173b), and noise figure in B2 in the B2-only non-carrier-aggregation mode when inter-stage notch filters are present (lower-most plot 173c). The group of three plots collectively indicated as 175 are for noise figure in B4 in the B2/B4 carrier-aggregation mode when inter-stage notch filters are present (upper-most plot 175a), noise figure in B4 in a B4-only non-carrier-aggregation mode when inter-stage notch filters are absent (lower-most plot 175c), and noise figure in B4 in the B4-only non-carrier-aggregation mode when inter-stage notch filters are present (middle plot 175b).

From the example comparisons of FIG. 11, a number of observations can be made. For example, it is noted that when operated in the B2/B4 carrier-aggregation mode, the noise figures in B2 (173a) and B4 (175a) bands with the inter-stage notch filters are significantly improved over the B2 and B4 noise FIGS. 172, 174) without such inter-stage notch filters.

In another example, it is noted that the noise figure performance in B2 in the carrier-aggregation mode (173a) is essentially the same as the noise figure performance in B2 in the non-carrier-aggregation modes with (173c) and without (173b) the inter-stage notch filters. For the B4 band, it is noted that the noise figure performance in the carrier-aggregation mode (175a) is slightly worse (about 0.13 dB) than the noise figure performance in the non-carrier-aggregation modes with (175b) and without (175c) the inter-stage notch filters.

FIG. 12 shows comparisons of gain (S21) (in dB) performance plots as a function of frequency for the example configuration of FIG. 9 and Tables 1 and 2. The group of plots on the left side of FIG. 12 correspond to B2 (1.930 GHz to 1.990 GHz for Rx), and the group of plots on the right side correspond to B4 (2.110 GHz to 2.155 GHz for Rx). For the B2 band, plot 176 is the gain in the B2 non-carrier-aggregation mode when inter-stage notch filters (130, 132 in FIG. 9) are absent (e.g., similar to the configuration of FIG. 7), plot 177 is the gain in the B2/B4 carrier-aggregation mode when the inter-stage notch filters are absent, plot 178 is the gain in the carrier-aggregation mode when the inter-stage notch filters are present, and plot 179 is the gain in the B2 non-carrier-aggregation mode when the inter-stage notch filters are present. For the B4 band, plot 180 is the gain in the B2/B4 carrier-aggregation mode when the inter-stage notch filters are absent, plot 181 is the gain in the B4 non-carrier-aggregation mode when the inter-stage notch filters are present, plot 182 is the gain in the carrier-aggregation mode when the inter-stage notch filters are present, and plot 183 is the gain in the B4 non-carrier-aggregation mode when the inter-stage notch filters are absent.

From the example comparisons of FIG. 12, it is noted that when in the B2/B4 carrier-aggregation mode, the B2 gain with the inter-stage notch filters (178) is higher than the B2 gain without the inter-stage notch filters (177). In the same carrier-aggregation mode, the B4 gain with the inter-stage notch filters (182) is lower than the B4 gain without the inter-stage notch filters (180).

Referring to the example of FIG. 12, it is also noted that when in the B2 non-carrier-aggregation mode, the B2 gain with the inter-stage notch filters (179) is higher than the B2 gain without the inter-stage notch filters (176). For the B4 non-carrier-aggregation mode, the B4 gain with the inter-stage notch filters (181) is also higher than the B4 gain without the inter-stage notch filters (183).

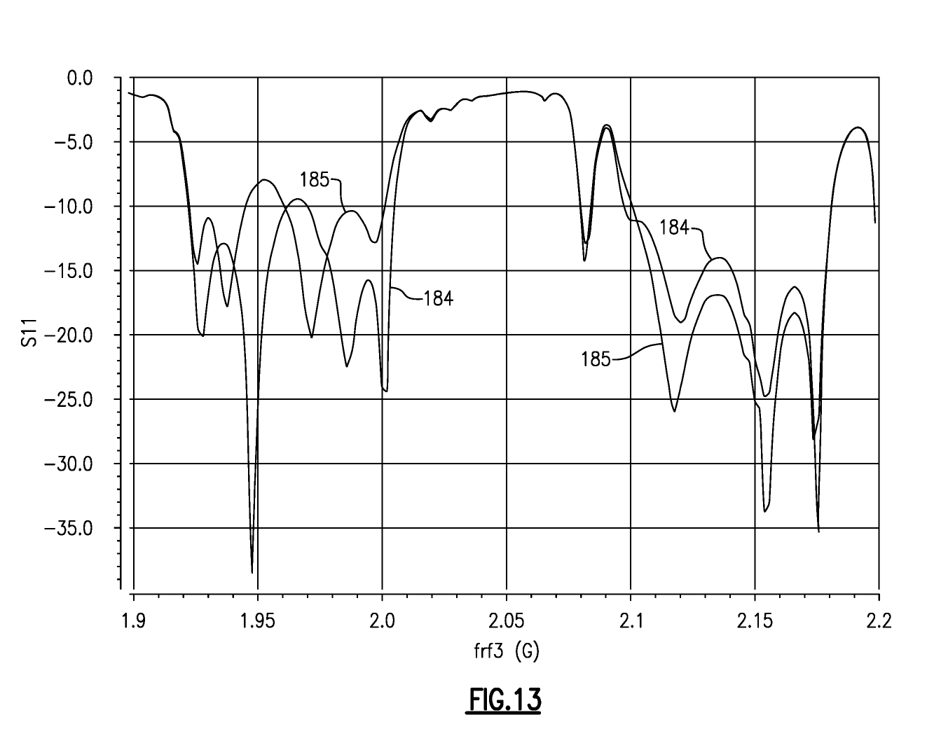

FIG. 13 shows comparisons of input return loss (S11) (in dB) plots as a function of frequency for the example configuration of FIG. 9 and Tables 1 and 2. Plot 184 is the input return loss in the B2/B4 carrier-aggregation mode when the inter-stage notch filters are absent; and plot 185 is the input return loss in the B2/B4 carrier-aggregation mode when the inter-stage notch filters are present. One can see that the input return loss in B2 is generally less with the inter-stage notch filters than that without. For the B4 band, one can see that the input return loss is generally more with the inter-stage notch filters than that without.

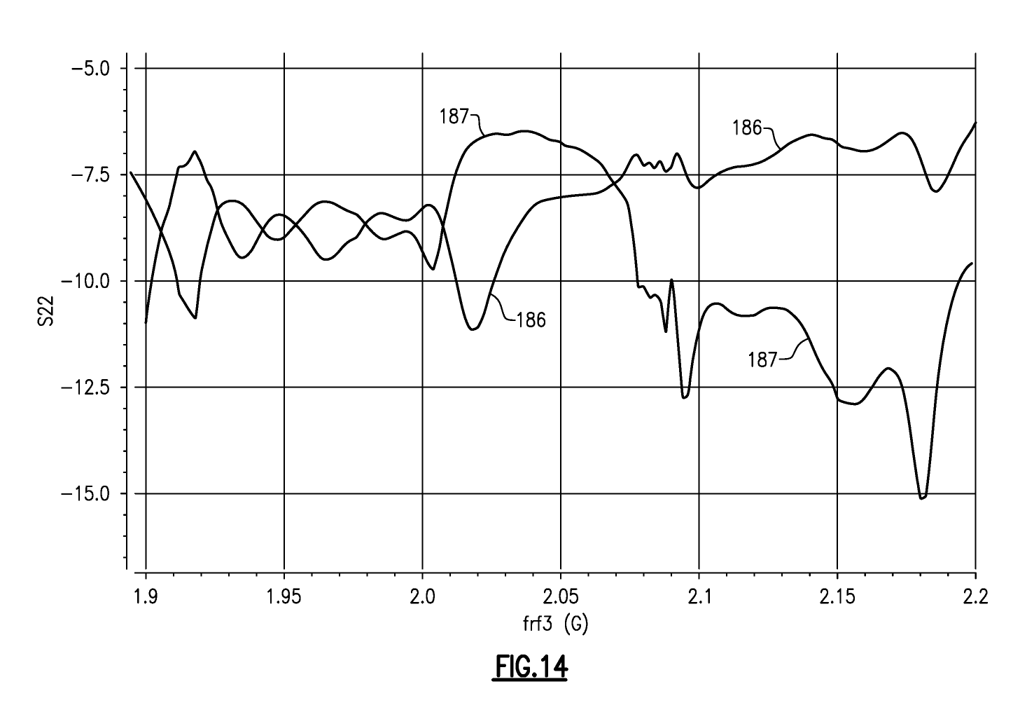

FIG. 14 shows comparisons of output return loss (S22) (in dB) plots as a function of frequency for the example configuration of FIG. 9 and Tables 1 and 2. Plot 187 is the output return loss in the B2/B4 carrier-aggregation mode when the inter-stage notch filters are absent; and plot 188 is the output return loss in the B2/B4 carrier-aggregation mode when the inter-stage notch filters are present. One can see that the output return losses in B2 is generally similar between the cases with and without the inter-stage notch filters. For the B4 band, one can see that the output return loss is generally less with the inter-stage notch filters than that without.

In the various examples described herein in reference to FIGS. 8-14, inter-stage filters are described as being notch filters configured to block out-of-band components. It will be understood that one or more features of the present disclosure can also be implemented using other types of filters as an inter-stage filter.

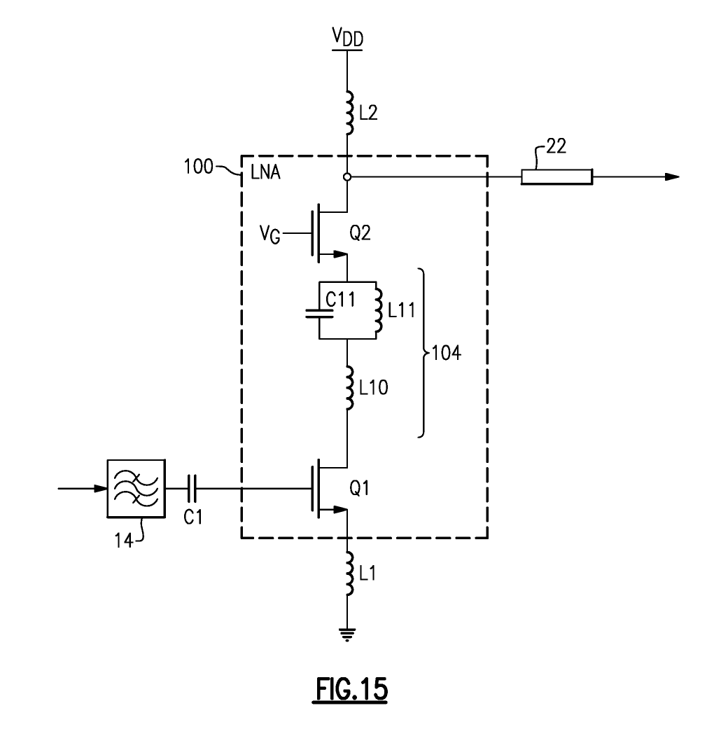

For example, FIG. 15 shows an LNA 100 having a band-pass filter 104 implemented between Q1 and Q2 of a cascode configuration. Arrangement of Q1 and Q2 in such a cascode arrangement, as well as examples of input and output, can be similar to the example of FIG. 5.

In the example of FIG. 15, a series combination of a capacitance C11 and an inductance L10 can be selected to resonate at an operating frequency (e.g., included in the band associated with the band-pass filter 104). An inductance L11 can be implemented to be parallel with the capacitance C11, and such an inductance (L11) can be relatively large to provide DC shorting functionality.

It will be understood that various inter-stage filters described herein are examples. It will also be understood that in some embodiments, any current-mode filter configured to operate at a desired frequency or frequency band can be utilized as an inter-stage filter.

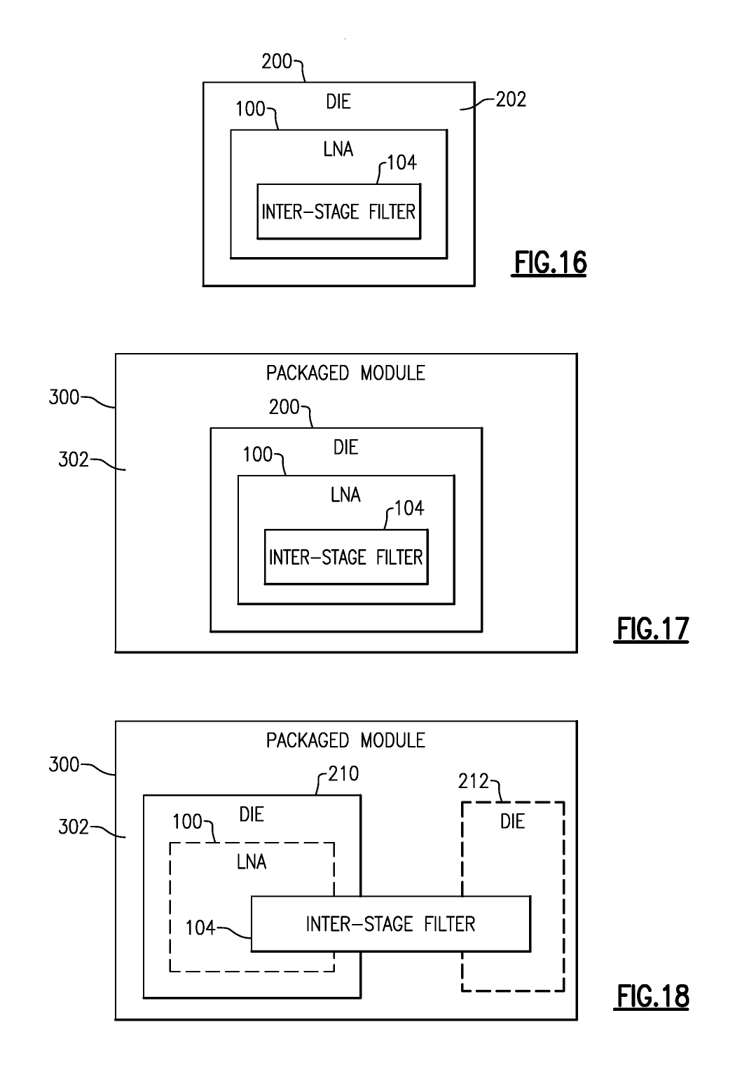

FIG. 16 shows that in some embodiments, some or all of an LNA 100 having one or more features as described herein can be implemented on a semiconductor die 200. Such a die can include a substrate 202, and some or all of one or more inter-stage filters 104 can be implemented on the substrate 202.

For example, the semiconductor substrate 202 can be a substrate suitable for implementation of the LNA 100. In the context of the example FETs described herein in reference to FIGS. 8 and 9, the semiconductor substrate 202 can be, for example, a silicon substrate, a silicon-germanium substrate, or a silicon-on-insulator (SOI) substrate. In another example, where bipolar-junction transistors (BJTs) are utilized in the LNA 100, the semiconductor substrate 202 can be, for example, a silicon substrate or a gallium arsenide substrate.

In some embodiments, some or all of the capacitances and inductances utilized for the inter-stage filter(s) 104 can be implemented on the foregoing semiconductor substrate. For example, a capacitance can be implemented as a MIM (metal-insulator-metal) capacitor, a MIS (metal-insulator-semiconductor) capacitor, a modified form of transistor, etc. An inductance can be implemented as a metal trace, a portion of a conductor, or some combination thereof.

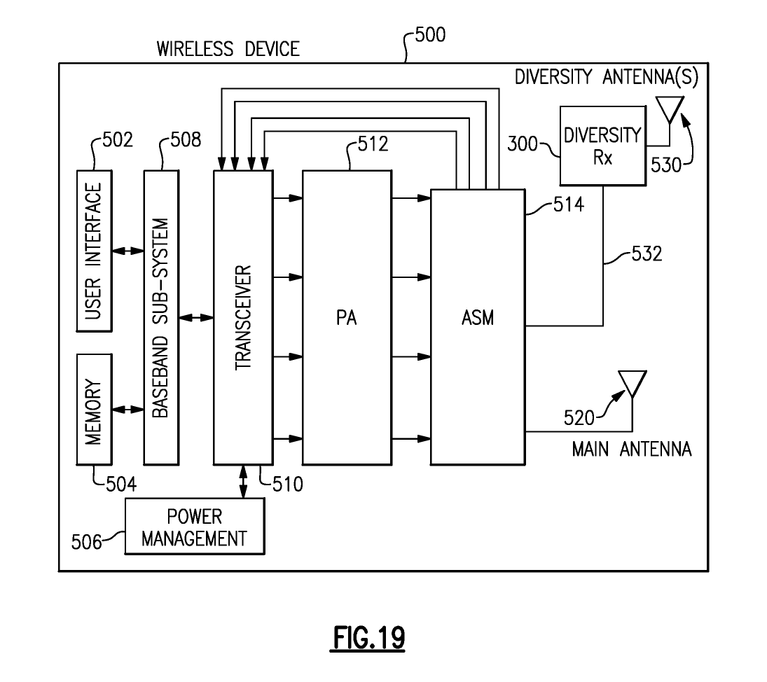

FIGS. 17 and 18 show that in some embodiments, some or all of an LNA 100 having one or more features as described herein can be implemented on a packaged module 300. Such a module can include a packaging substrate 302 configured to receive a plurality of components such as one or more die and one or more passive components.

FIG. 17 shows that in some embodiments, the packaged module 300 can include a semiconductor die 200 that is similar to the example of FIG. 16. Accordingly, such a die can include substantially all of the LNA 100, and some or all of one or more inter-stage filters 104 being implemented on the die 200.

FIG. 18 shows that in some embodiments, the packaged module 300 can include a first semiconductor die 210 having an LNA 100 implemented thereon. In the example of FIG. 18, some of one or more inter-stage filters 104 can be implemented on the first die 210, and the rest of the one or more inter-stage filters 104 can be implemented on another die 212, outside of a die (e.g., on the packaging substrate 302), or any combination thereof.

In some implementations, an architecture, device and/or circuit having one or more features described herein can be included in an RF device such as a wireless device. Such an architecture, device and/or circuit can be implemented directly in the wireless device, in one or more modular forms as described herein, or in some combination thereof. In some embodiments, such a wireless device can include, for example, a cellular phone, a smart-phone, a hand-held wireless device with or without phone functionality, a wireless tablet, a wireless router, a wireless access point, a wireless base station, etc. Although described in the context of wireless devices, it will be understood that one or more features of the present disclosure can also be implemented in other RF systems such as base stations.

FIG. 19 depicts an example wireless device 500 having one or more advantageous features described herein. In some embodiments, an LNA having one or more features as described herein can be implemented in each of one or more places in such a wireless device. For example, in some embodiments, such advantageous features can be implemented in a module such as a diversity receive (DRx) module 300 having one or more low-noise amplifiers (LNAs).

In the example of FIG. 19, power amplifiers (PAs) in a PA module 512 can receive their respective RF signals from a transceiver 510 that can be configured and operated to generate RF signals to be amplified and transmitted, and to process received signals. The transceiver 510 is shown to interact with a baseband sub-system 508 that is configured to provide conversion between data and/or voice signals suitable for a user and RF signals suitable for the transceiver 510. The transceiver 510 is also shown to be connected to a power management component 506 that is configured to manage power for the operation of the wireless device 500. Such power management can also control operations of the baseband sub-system 508 and other components of the wireless device 500.

The baseband sub-system 508 is shown to be connected to a user interface 502 to facilitate various input and output of voice and/or data provided to and received from the user. The baseband sub-system 508 can also be connected to a memory 504 that is configured to store data and/or instructions to facilitate the operation of the wireless device, and/or to provide storage of information for the user.

In the example of FIG. 19, the DRx module 300 can be implemented between one or more diversity antennas (e.g., diversity antenna 530) and the ASM 514. Such a configuration can allow an RF signal received through the diversity antenna 530 to be processed (in some embodiments, including amplification by an LNA) with little or no loss of and/or little or no addition of noise to the RF signal from the diversity antenna 530. Such processed signal from the DRx module 300 can then be routed to the ASM through one or more signal paths.

In the example of FIG. 19, a main antenna 520 can be configured to, for example, facilitate transmission of RF signals from the PA module 512. In some embodiments, receive operations can also be achieved through the main antenna.

A number of other wireless device configurations can utilize one or more features described herein. For example, a wireless device does not need to be a multi-band device. In another example, a wireless device can include additional antennas such as diversity antenna, and additional connectivity features such as Wi-Fi, Bluetooth, and GPS.

One or more features of the present disclosure can be implemented with various cellular frequency bands as described herein. Examples of such bands are listed in Table 3. It will be understood that at least some of the bands can be divided into sub-bands. It will also be understood that one or more features of the present disclosure can be implemented with frequency ranges that do not have designations such as the examples of Table 3.

TABLE 3

| | | Tx Frequency Range | Rx Frequency Range |
|---|---|---|---|
| Band | Mode | (MHz) | (MHz) |
| B1 | FDD | 1,920-1,980 | 2,110-2,170 |
| B2 | FDD | 1,850-1,910 | 1,930-1,990 |
| B3 | FDD | 1,710-1,785 | 1,805-1,880 |
| B4 | FDD | 1,710-1,755 | 2,110-2,155 |
| B5 | FDD | 824-849 | 869-894 |
| B6 | FDD | 830-840 | 875-885 |
| B7 | FDD | 2,500-2,570 | 2,620-2,690 |
| B8 | FDD | 880-915 | 925-960 |
| B9 | FDD | 1,749.9-1,784.9 | 1,844.9-1,879.9 |
| B10 | FDD | 1,710-1,770 | 2,110-2,170 |
| B11 | FDD | 1,427.9-1,447.9 | 1,475.9-1,495.9 |
| B12 | FDD | 699-716 | 729-746 |
| B13 | FDD | 777-787 | 746-756 |
| B14 | FDD | 788-798 | 758-768 |
| B15 | FDD | 1,900-1,920 | 2,600-2,620 |
| B16 | FDD | 2,010-2,025 | 2,585-2,600 |
| B17 | FDD | 704-716 | 734-746 |
| B18 | FDD | 815-830 | 860-875 |
| B19 | FDD | 830-845 | 875-890 |
| B20 | FDD | 832-862 | 791-821 |
| B21 | FDD | 1,447.9-1,462.9 | 1,495.9-1,510.9 |
| B22 | FDD | 3,410-3,490 | 3,510-3,590 |
| B23 | FDD | 2,000-2,020 | 2,180-2,200 |
| B24 | FDD | 1,626.5-1,660.5 | 1,525-1,559 |
| B25 | FDD | 1,850-1,915 | 1,930-1,995 |
| B26 | FDD | 814-849 | 859-894 |
| B27 | FDD | 807-824 | 852-869 |
| B28 | FDD | 703-748 | 758-803 |
| B29 | FDD | N/A | 716-728 |
| B30 | FDD | 2,305-2,315 | 2,350-2,360 |
| B31 | FDD | 452.5-457.5 | 462.5-467.5 |
| B33 | TDD | 1,900-1,920 | 1,900-1,920 |
| B34 | TDD | 2,010-2,025 | 2,010-2,025 |
| B35 | TDD | 1,850-1,910 | 1,850-1,910 |
| B36 | TDD | 1,930-1,990 | 1,930-1,990 |
| B37 | TDD | 1,910-1,930 | 1,910-1,930 |
| B38 | TDD | 2,570-2,620 | 2,570-2,620 |
| B39 | TDD | 1,880-1,920 | 1,880-1,920 |
| B40 | TDD | 2,300-2,400 | 2,300-2,400 |
| B41 | TDD | 2,496-2,690 | 2,496-2,690 |
| B42 | TDD | 3,400-3,600 | 3,400-3,600 |
| B43 | TDD | 3,600-3,800 | 3,600-3,800 |
| B44 | TDD | 703-803 | 703-803 |

It is noted that while some examples are described herein in the context of carrier aggregation of two bands, one or more features of the present disclosure can also be implemented in configurations involving carrier aggregation of different numbers of bands.

It is noted that while various examples are described herein in the context of inter-stage filters, it will be understood that one or more features of the present disclosure can also be implemented with a non-filter inter-stage circuit. Thus, in accordance with a more general concept, an inter-stage circuit can be a circuit implemented between an input stage and an output stage of an amplifier such as a cascode amplifier. In some embodiments, such an inter-stage circuit can be configured to operate in a current mode to condition a signal provided by the input stage.

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. An amplifier assembly for amplifying a signal, comprising:
an input amplification stage;
an output amplification stage; and
an inter-stage filter implemented between the input amplification stage and the output amplification stage.

2. The amplifier assembly of claim 1 wherein the amplifier is a low-noise amplifier.

3. The amplifier assembly of claim 2 wherein the low-noise amplifier is implemented in a cascode configuration.

4. The amplifier assembly of claim 3 wherein the input amplification stage includes a common emitter transistor, and the output amplification stage includes a common base transistor.

5. The amplifier assembly of claim 3 wherein the input amplification stage includes a common source transistor, and the output amplification stage includes a common gate transistor.

6. The amplifier assembly of claim 3 wherein each of the input amplification stage and the output amplification stage is configured to provide amplification for a signal in a first frequency band.

7. The amplifier assembly of claim 6 wherein the inter-stage filter is a band-pass filter configured for the first frequency band.

8. The amplifier assembly of claim 6 wherein the inter-stage filter is a notch filter configured to block a second frequency band outside of the first frequency band.

9. The amplifier assembly of claim 8 wherein the input amplification stage and the output amplification stage are parts of a first amplification path, such that the input amplification stage is a first input stage, the output amplification stage is a first output stage, and the inter-stage filter is a first inter-stage notch filter.

10. The amplifier assembly of claim 9 further comprising a second amplification path having a second input stage and a second inter-stage notch filter.

11. The amplifier assembly of claim 10 wherein the second amplification path further includes the first output stage of the first amplification path as a common output stage.

12. The amplifier assembly of claim 11 wherein the second inter-stage notch filter is configured to block the first frequency band.

13. The amplifier assembly of claim 12 wherein each of the first inter-stage notch filter and the second inter-stage notch filter includes a parallel combination of a capacitance and an inductance.

14. The amplifier assembly of claim 13 wherein each of the first inter-stage notch filter and the second inter-stage notch filter further includes a grounding path at a node between the parallel combination and the corresponding input stage, the grounding path including a series combination of a capacitance and an inductance.

15. The amplifier assembly of claim 14 wherein the second inter-stage notch filter further includes an additional grounding path at the node, the additional grounding path including a capacitance.

16. The amplifier assembly of claim 15 wherein the first frequency band has an upper limit of a frequency range that is lower than a lower limit of a frequency range of the second frequency band.

17. (canceled)

18. The amplifier assembly of claim 1 wherein each of the input amplification stage, the output amplification stage, and the inter-stage filter is configured to process a radio-frequency signal.

19. The amplifier assembly of claim 1 wherein the inter-stage filter is implemented at a node between the input amplification stage and the output amplification stage, at least the node of the amplifier assembly configured to operate in a current mode.

20. (canceled)

21. (canceled)

22. (canceled)

23. (canceled)

24. (canceled)

25. (canceled)

26. (canceled)

27. A packaged module for processing a signal, comprising:
a packaging substrate configured to receive a plurality of components;
an amplifier implemented on the packaging substrate, and including an input amplification stage and an output stage; and
an inter-stage filter implemented between the input amplification stage and the output amplification stage, the inter-stage filter formed on the packaging substrate.

28. (canceled)

29. (canceled)

30. (canceled)

31. A wireless device comprising:
an antenna configured to receive a signal;
an amplifier assembly in communication with the antenna and configured to amplify the signal, the amplifier assembly including an input amplification stage and an output stage, the amplifier assembly further including an inter-stage filter implemented between the input amplification stage and the output amplification stage; and
a transceiver in communication with the amplifier assembly and configured to process the amplified signal.

32-60. (canceled)
